(19) United States
(12) Patent Application Publication
(10) Pub. No.: US 2004/0145058 A1
(43) Pub. Date: Jul. 29, 2004

(54) Buried connections in an integrated circuit substrate

(76) Inventors: Michel Marty, Saint Paul De Varces (FR); Francois Leverd, Saint-Ismier (FR); Philippe Coronel, Barraux (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/735,518

(22) Filed: Dec. 12, 2003

(30) Foreign Application Priority Data
Dec. 13, 2002 (FR) 02/ 15837

(51) Int. Cl. H01L 23/48

(52) U.S. Cl. 257/758

(57) ABSTRACT

A method for manufacturing buried connections in an integrated circuit, including the steps of: providing a structure formed of a first support wafer glued at the rear surface of a thin semiconductor wafer, one or several elements of the integrated circuit being possibly formed in and above the thin wafer; gluing a second support wafer on the structure on the front surface side of the thin wafer; removing the first support wafer; forming connections between different areas of the rear surface of the thin wafer; gluing a third support wafer on the connections; and removing the second support wafer.

### BACKGROUND OF THE INVENTION

1. Field of the Invention

The present invention relates to the field of integrated circuits.

The present invention more specifically relates to integrated circuits comprising buried layers in the circuit substrate. Such buried layers are used to decrease the access resistance to an electrode of a transistor when the access to this electrode is performed through a substrate portion.

2. Discussion of the Related Art

An example of a structure comprising a buried layer enabling reduction of the access resistance of the collector of a bipolar transistor is described in U.S. patent application Ser. No. 10/678,954, which is incorporated herein by reference.

### SUMMARY OF THE INVENTION

An object of the present invention is to provide an integrated circuit having a structure such that the resistance of access to layers buried in the substrate is very small.

Another object of the present invention is to provide an integrated circuit comprising a network of buried interconnections to interconnect different semiconductor areas formed in a substrate and to connect substrate areas to elements accessible through the mesh network formed above the integrated circuit components.

To achieve these and other objects, the present invention provides a method for manufacturing buried connections in an integrated circuit, comprising the steps of providing a structure formed of a first support wafer glued at the rear surface of a thin semiconductor wafer, one or several elements of the integrated circuit being possibly formed in and above the thin wafer; gluing a second support wafer on the structure on the front surface side of the thin wafer; removing the first support wafer; forming connections between different areas of the rear surface of the thin wafer; gluing a third support wafer on the connections; and removing the second support wafer.

According to another embodiment of the invention, the thin wafer and the first support wafer are glued via an insulating layer.

According to another embodiment of the invention, the step of forming the connections comprises the steps of etching openings in an insulating layer formed on the rear surface of the thin wafer; and filling the openings with a conductive material.

According to another embodiment of the invention, the method further comprises after the step of etching openings in the insulating layer, a step of etching areas of reduced thickness in the insulating layer, the areas of reduced thickness being then filled like said openings with a conductive material.

According to another embodiment of the invention, the filling of the openings with a conductive material comprises depositing a metal layer on the structure on the side of the insulating layer and of the openings; annealing to form a silicide layer at the bottom of the openings.

According to another embodiment of the invention, the method comprises, after the step of filling the openings and possibly the areas of reduced thickness, the step of: performing a chem-mech polishing of the conductive filling material to expose the insulating layer to obtain a planar surface; covering said planar surface with a second insulating layer; and gluing the third support wafer on the second insulating layer.

According to another embodiment of the invention, the method comprises, prior to the gluing of the second support wafer, a step of covering the structure with a bonding layer.

The present invention also provides an integrated circuit comprising components formed in and above a thin semiconductor wafer attached on a support wafer placed at the rear surface of the thin wafer, the rear surface of the thin wafer being covered with a first insulating layer comprising openings containing a conductive material in contact with some areas of the rear surface of the thin wafer.

According to another embodiment of the invention, some areas of the conductive metal are in contact with conductive wells crossing the thin wafer.

According to another embodiment of the invention, said conductive areas and possibly said conductive wells are made of silicide.

According to another embodiment of the invention, the insulating layer comprises areas of reduced thickness containing a conductive material forming connections between the openings.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1 is a cross-section view of an integrated circuit formed according to the present invention;

FIGS. 2 to 8 are cross-section views illustrating structures obtained after successive steps of a connection manufacturing method according to the present invention;

FIGS. 9 to 11 are cross-section views illustrating the structure obtained after some steps of another embodiment of the method of the present invention; and

FIGS. 12 and 13 are cross-section views illustrating the structures obtained after some steps of another embodiment of the method of the present invention.

### DETAILED DESCRIPTION

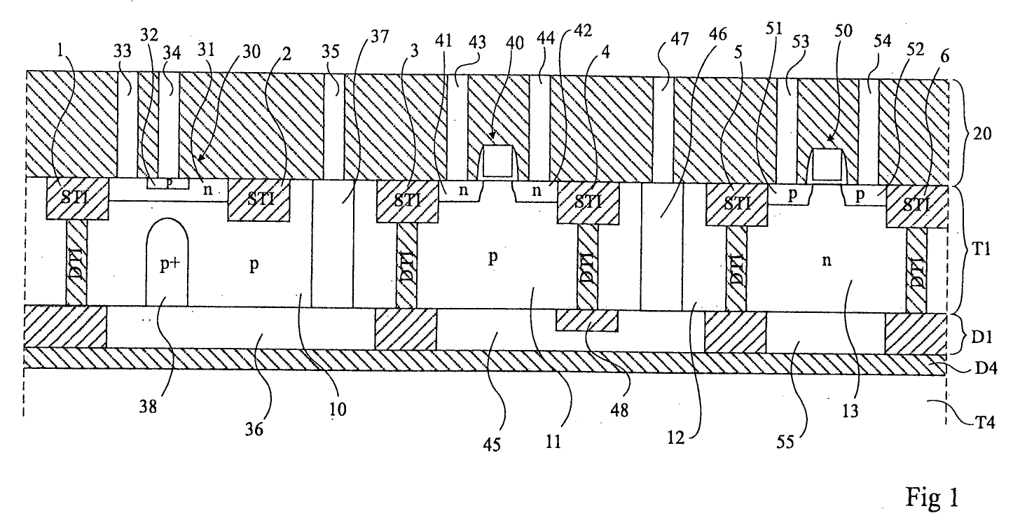

FIG. 1 is a cross-section view of an integrated circuit portion in which are formed buried interconnections according to the present invention. The integrated circuit components are formed in and above a thinned down semiconductor wafer T1 of a thickness on the order of from a few μm to a few tens of μm. The lower surface of wafer T1 is covered with an insulating layer D1. A wafer T4, for example, silicon, is glued under insulating layer D1, via an insulating layer D4, for example, a TEOS oxide layer. Wafer T4 is essentially used as a rigid support for thinned wafer T1.

Shallow trench insulation areas STI are formed in the upper surface of wafer T1. The shown structure comprises six shallow trench insulation areas STI 1 to 6, respectively, from left to right. Deep trench insulation areas DTI, reaching down to the upper surface of insulating layer D1, are formed under certain selected shallow trench insulation areas STI, that is, areas 1, 3, 4, 5, and 6 in this example. The deep trench insulation areas DTI delimit substrate wells in which are formed the integrated circuit components. In the shown example, four wells 10, 11, 12, 13, respectively, from left to right, are delimited. An insulating layer 20 covers thin wafer T1 and the components formed thereon.

A bipolar transistor 30 is formed in initially P-doped well 10. Shallow insulation area 2 delimits two regions. In the left-hand region is formed an N-doped shallow area forming base 31 of transistor 30, in which is formed a very shallow P-doped area forming emitter 32 of transistor 30. The base and the emitter are accessible by contacts 33 and 34 formed in insulating layer 20. The rest of the P-doped well forms the collector of transistor 30. A contact 35 is placed above the right-hand region of well 10 to have access to the collector.

A collector well 37 crosses thin wafer T1 under contact 35. A heavily-doped P region 38 is formed in the collector under the emitter. Collector well 37 and area 38 enable decreasing the collector access resistance.

According to an aspect of the present invention, a metal region 36 is provided under the lower surface of well 10. Metal region 36 is formed in an opening of insulating layer D1. Metal region 36 connects collector well 37 and heavily-doped P area 38 to significantly decrease the access resistance of the collector of transistor 30.

An NMOS transistor 40 is formed in P doped well 11. N-doped source/drain areas 41 and 42 are accessible through contacts 43 and 44 crossing insulating layer 20. The thin oxide, the gate, and the spacers of transistor 40 are formed above wafer T1 between source/drain areas 41 and 42.

According to an aspect of the present invention, well 11 of transistor 40 is connected to a supply terminal via a metal region 45 formed in insulating layer D1. One end of metal region 45 is in contact with the lower surface of well 11. The other end of metal region 45 is in contact with the lower surface of well 12. A conductive well 46 crossing thin wafer T1 is formed in well 12. A contact 47 enables connecting conductive well 46 to a supply terminal via the “upper” mesh network, not shown, formed above the integrated circuit components.

In the structure example shown in FIG. 1, wells 11 and 12 are next to each other. Now, it is not always possible to place the wells which are desired to be connected close to one another. In this case, contact areas are formed in openings of insulating layer D1 under the wells and the connection areas connecting these contact areas are formed in a portion only of the thickness of insulating layer D1, on the side of insulating layer D4. Although, in this example, a large opening formed under the two wells would have been sufficient, an area of reduced thickness 48 has been shown for illustration under the deep insulating area separating wells 11 and 12.

A PMOS transistor 50 is formed in N-doped well 13. P-doped source/drain areas 51 and 52 are accessible by contacts 53 and 54. The thin oxide, the gate, and the spacers of transistor 50 are formed above wafer T1 between source/drain areas 51 and 52. According to the present invention, a metal region 55 formed in insulating layer D1 is in contact with the lower surface of active area 13. Metal region 55 enables connecting well 13 to a supply source, not shown, via as previously a conductive pad crossing wafer T1 and the “upper” mesh network.

The integrated circuit structure of the present invention comprising buried conductive areas insulated from one another enables forming different types of connections. It is thus possible to form “local” connections by forming metal regions under certain substrate portions to reduce their resistance. It is further possible to form “long” connections between different substrate areas by defining areas of lesser thickness in insulating layer D1.

An advantage of the integrated circuit structure of the present invention is that it is possible to provide buried local connections and long connections.

Further, such a structure enables connecting any semiconductor area formed on the lower surface side of wafer T1 to an electrode of a transistor or of any other component of the integrated circuit via a conductive well crossing thin layer T1 and the mesh network formed above the components. Moreover, such a structure enables connecting two electrodes via two conductive wells and a buried connection.

It could, for example, be provided to supply an entire well in which are formed several components or several individual wells by using a restricted number of conductive wells connected to an assembly of connections formed in the insulating layer and connected to a supply voltage source.

Further, different kinds of conductive wells crossing thin wafer T1 may be formed to connect a buried conductive area and the upper connection network (above the integrated circuit components). An opening with an insulated wall filled with a conductive material such as a metal or heavily-doped polysilicon may, for example, be formed.

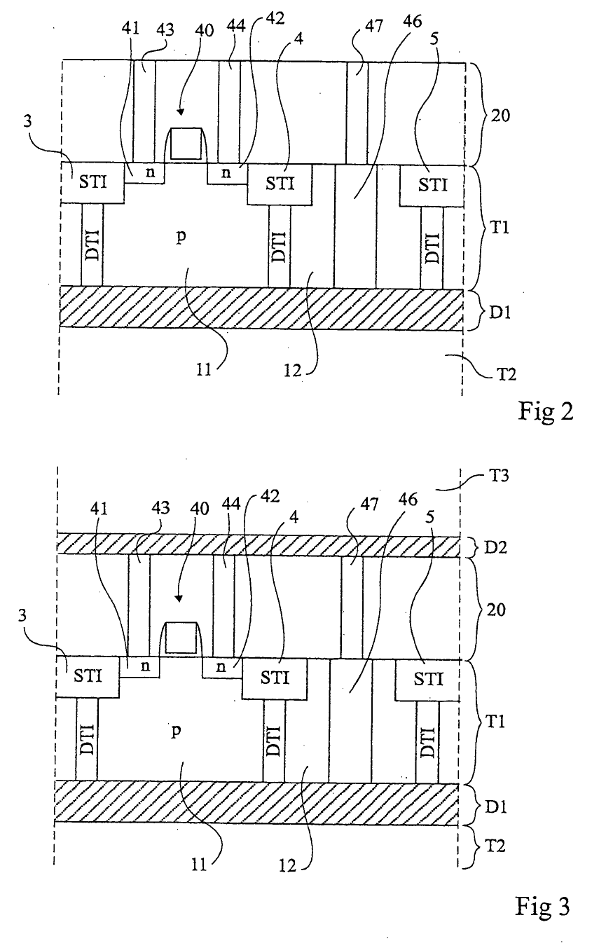

FIGS. 2 to 8 illustrate different steps of a method for forming buried interconnections according to the present invention.

FIG. 2 shows an initial integrated circuit structure comprising two semiconductor wafers, a very thin wafer T1 of a thickness of a few μm, and a thicker wafer T2 used as a rigid support. Wafers T1 and T2 are separated by an insulating layer D1. This structure may be obtained according to a conventional silicon-on-insulator, also called SOI, manufacturing process.

The integrated circuit components are formed in and above wafer T1. As described previously in relation with FIG. 1, the structure shown in FIG. 2 comprises an NMOS transistor 40 having its source and drain 41 and 42 formed in a well 11 separated from a well 12 via a shallow insulating area 4 under which is formed a deep insulating area DTI. Thin wafer T1 and transistor 40 are covered with an insulating layer 20. Contacts 43 and 44 enable accessing to drain and source 41 and 42. A contact 47 enables accessing to one end of a conductive well 46 crossing wafer T1, the other end of conductive well 46 being in contact with insulating layer D1.

In a first step illustrated in FIG. 3, a support wafer T3 is glued on insulating layer 20 according to a conventional molecular gluing method, for example, via a bonding layer D2 formed under insulating layer 20.

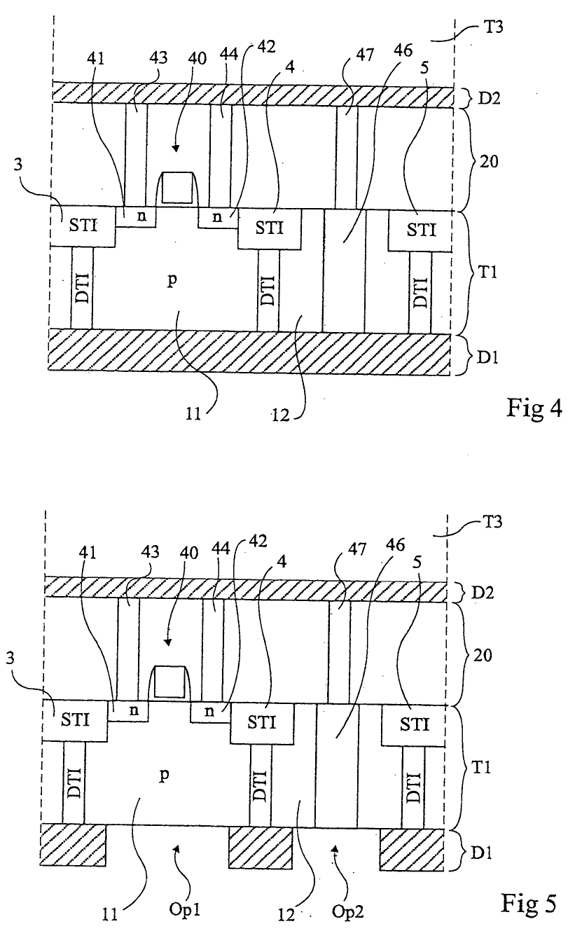

In a second step illustrated in FIG. 4, wafer T2 is selectively etched with respect to insulating layer D1. Wafer T2 is completely removed.

The gluing of wafer T3 performed prior to the etching of wafer T2 is used to ensure that the structure is sufficiently robust to perform without a problem operations in the lower structure portion.

The next steps illustrated in FIGS. 5, 6, and 7 aim at forming metal connections between different contact areas defined on the lower surface of wafer T1. In the example of the structure shown in FIGS. 2 to 8, it is desired to connect well 11 to a conductive well 46 via a buried connection formed under wafer T1.

In a third step illustrated in FIG. 5, openings are etched in insulating layer D1 to expose contact areas on the lower surface of wafer T1. In this example, openings Op1 and Op2 are respectively formed under wells 11 and 12.

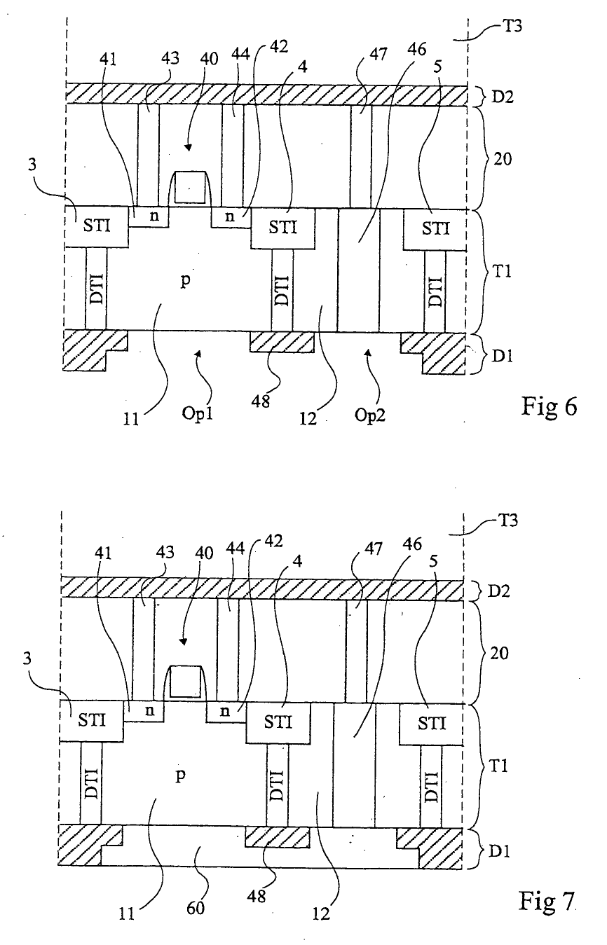

In a fourth step illustrated in FIG. 6, the thickness of insulating layer D1 is reduced at the locations where a connection is desired to be formed between several previously-formed openings. In this example, openings Op1 and Op2 are connected by an area of reduced thickness 48.

In a fifth step illustrated in FIG. 7, openings Op1 and Op2 and the areas of reduced thickness, t, are filled with a conductive material 60 such as copper. Conventionally, a copper layer is deposited on insulating layer D1 and a chem-mech polishing of the copper layer is performed to expose insulating layer D1. Such a chem-mech polishing enables obtaining a planar lower surface.

The method described in relation with FIGS. 6 and 7 corresponds to the conventional copper interconnection forming method. However, it may be provided to use other interconnection forming methods such as that conventionally used to form aluminum connections.

Further, it may possibly be provided to form several interconnection levels according to conventional methods to further increase the number of connections.

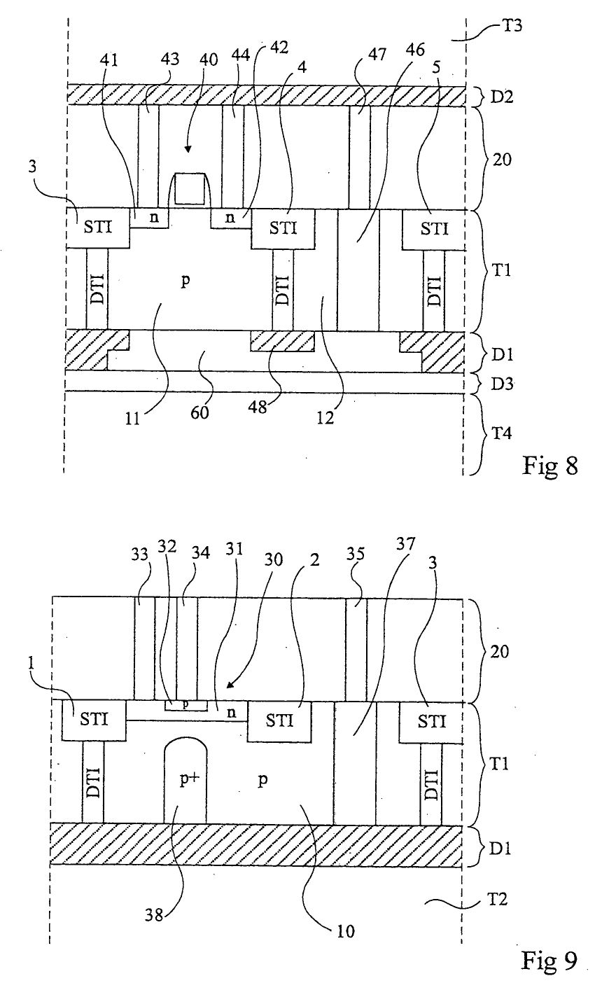

In a sixth step illustrated in FIG. 8, the previously polished planar lower surface is covered with an insulating layer D3. A support wafer T4 is then glued on insulating layer D3. An insulating layer and a support wafer that can be glued to each other with no other intermediaries will preferably be chosen.

Wafer T3 is then selectively etched with respect to bonding layer D2 to completely remove wafer T3. Bonding layer D2 is then removed according to a selective etch of bonding layer D2 with respect to insulating layer 20 or by performing a chem-mech polishing.

Wafers T3 and T4 have the function of ensuring that the structure has a sufficient rigidity and robustness. Other materials capable of being easily glued on an insulating layer may be used to perform this function.

An alternative embodiment of the method of the present invention is described in relation with FIGS. 9 to 11.

FIG. 9 shows an initial structure comprising, as with the structure described in relation with FIG. 2, a thin layer T1 separated from a support wafer T2 by an insulating layer D1. An insulating layer 20 covers wafer T1. A bipolar transistor 30 identical to that described in relation with FIG. 1 is formed in a well 10 of wafer T1. The collector of transistor 30 comprises, as previously, a heavily-doped P-type area 38 formed right under emitter 32. A contact 35 enables access to a collector well 37 crossing well 10. Collector well 37 is in this example a heavily-doped substrate area or polysilicon formed in an opening with insulating walls.

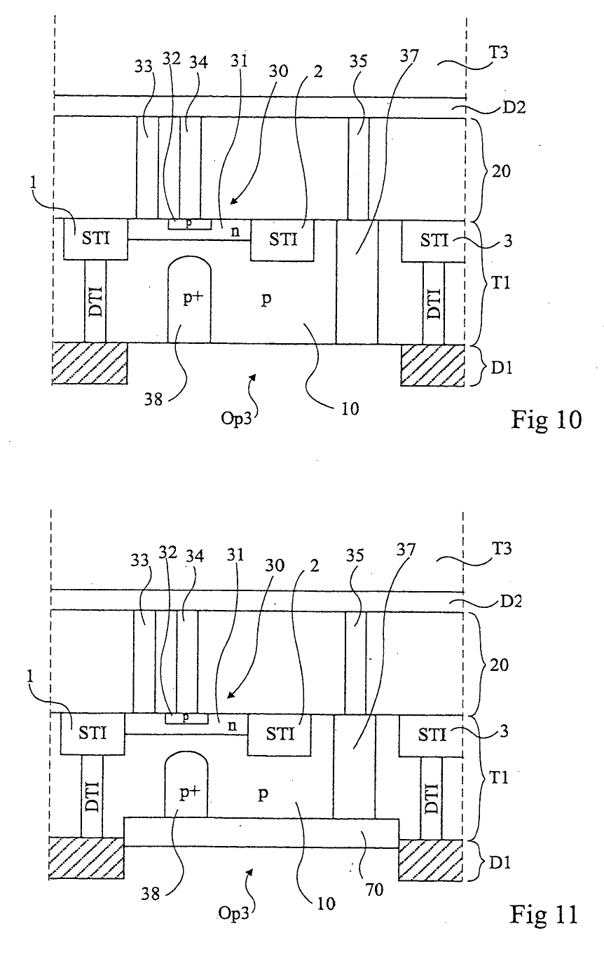

FIG. 10 illustrates the structure obtained at the end of the previously-described first, second, and third steps of the method of the present invention. An opening Op3 of insulating layer D1 is formed under well 10 of transistor 30.

FIG. 11 illustrates the structure obtained at the end of a silicide forming step performed from the structure described in FIG. 10. For this purpose, metal such as nickel, cobalt, tungsten, or titanium is deposited in a first phase on the side of insulating layer D1. In a second phase, an anneal is performed to form a silicide layer 70 at the bottom of opening Op3 previously formed in insulating layer D1. Then, in a last phase, the metal which has not been turned into silicide is removed.

A chem-mech polishing of the remaining portions of insulating layer D1 is then performed to obtain a planar surface. The sixth step of the method of the present invention, which comprises covering the polished surface with an insulating bonding layer D3 and of gluing thereon a support wafer T4, is then carried out, wafer T3 and bonding layer D2 being then removed.

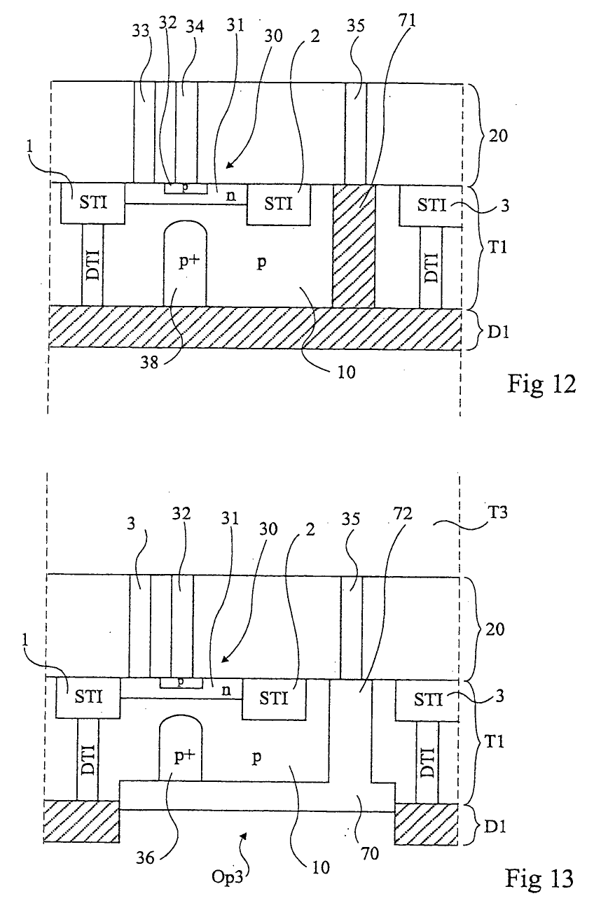

Another alternative embodiment of the method of the present invention is described in relation with FIGS. 12 and 13.

FIG. 12 shows another initial structure of a bipolar transistor identical to that described in FIG. 9, except that collector well 37 is replaced with an insulating pillar 71 crossing well 10, the pillar being formed under contact 35 enabling access to the transistor collector. Pillar 71 is formed of an insulating material which may be preferably etched according to the same method as that enabling etching of insulating layer D1.

Based on the initial structure shown in FIG. 12, the previously-described first, second, and third steps of the method of the present invention are performed. An opening Op3 is formed in insulating layer D1 under the transistor collector. The etching of insulating layer D1 is provided to be sufficiently long to totally etch insulating pillar 71.

FIG. 13 illustrates the structure obtained at the end of a subsequent silicide-forming step performed according to a method similar to that described previously. Insulating pillar 71 is integrally replaced with a silicide pad 72.

Of course, the present invention is likely to have various alterations, modifications, and improvements which will readily occur to those skilled in the art. In particular, it may be provided to implement the method of the present invention before forming the integrated circuit elements in wafer T1 or, conversely, at the very end of the integrated circuit component manufacturing process or, generally, after any step of the integrated circuit component manufacturing process.

Generally, the method of the present invention applies to any structure comprising an initial support wafer glued at the rear surface of a thin semiconductor wafer. The initial support wafer may be glass or any other material. The method then provides gluing a “relay” support wafer on the front surface side of the thin wafer and removing the initial support wafer. An assembly of “local” and/or “long” connections is then formed on the rear surface of the thin wafer according to a conventional interconnection forming method. Then, the mesh network is covered with a final support wafer and the relay support wafer is removed.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for manufacturing buried connections in an integrated circuit, comprising:
providing a structure formed of a first support wafer glued onto a rear surface of a thin semiconductor wafer, one or several elements of the integrated circuit being possibly formed in and above the thin wafer;
gluing a second support wafer on the structure on the front surface side of the thin wafer;
removing the first support wafer;
forming connections between different areas of the rear surface of the thin wafer;
gluing a third support wafer on the connections; and
removing the second support wafer.

2. The method of claim 1, wherein the thin wafer and the first support wafer are glued via an insulating wafer.

3. The method of claim 1, wherein the step of forming the connections comprises the steps of:
etching openings in an insulating layer formed on the rear surface of the thin wafer; and
filling the openings with a conductive material.

4. The method of claim 3, further comprising after the step of etching openings in the insulating layer, a step of etching areas of reduced thickness in the insulating layer, the areas of reduced thickness being then filled like said openings with a conductive material.

5. The method of claim 3, wherein the filling of the openings with a conductive material comprises:
depositing a metal layer on the structure on the side of the insulating layer and of the openings;
annealing to form a silicide layer at the bottom of the openings.

6. The method of claim 3, comprising, after the step of filling the openings and possibly the areas of reduced thickness:
performing a chem-mech polishing of the conductive filling material to expose the insulating layer to obtain a planar surface;
covering said planar surface with a second insulating layer; and
gluing the third support wafer on the second insulating layer.

7. The method of claim 1, comprising, prior to the gluing of the second support wafer, a step of covering the structure with a bonding layer.

8. An integrated circuit comprising components formed in and above a thin semiconductor wafer attached on a support wafer placed at the rear surface of the thin wafer, the rear surface of the thin wafer being covered with a first insulating layer comprising openings cross the thin wafer, the openings containing conductive portions in contact with some areas of the rear surface of the thin semiconductor wafer, said conductive portions being made of silicide.

9. The integrated circuit of claim 8, wherein some of the said conductive portions are in contact with conductive wells crossing the thin wafer, the conductive wells being eventually made of silicide.
